(19) United States
(12) Patent Application Publication
(10) Pub. No.: US 2026/0011634 A1
(43) Pub. Date: Jan. 8, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yen-Chang CHEN, Tainan City (TW); Wei-Hang HUANG, Tainan City (TW); Chieh-En CHEN, Tainan City (TW); Chang-Chia LU, Tainan City (TW); Wei-Chih WENG, Tainan City (TW); Chen-Hsien LIN, Tainan City (TW); Shyh-Fann TING, Tainan City (TW)

(21) Appl. No.: 18/761,505

(22) Filed: Jul. 2, 2024

(51) Int. Cl. H01L 23/522

(52) U.S. Cl. CPC H01L 23/5223; H10D 1/042; H10D 1/716

(57) ABSTRACT

A trench for a trench capacitor structure is formed using a metal-containing masking layer. The metal-containing masking layer enables the layers of a semiconductor device to be etched to form the trench in a manner that reduces and/or minimizes corner rounding at the top of the trench. In particular, the metal-containing masking layer suppresses etching in the corners at the top of the trench in that the metal masking-containing layer can be used for multiple etch operations and does not need to be removed between etch operations because of contamination concerns. This enables the metal-containing masking layer to be used to fully form the trench, which enables the metal-containing masking layer to protect the top of the trench from corner rounding.

### BACKGROUND

A semiconductor device may include one or more capacitor structures in an interconnect layer (e.g., a back end of line (BEOL) region or back end region) above a device layer. A capacitor structure may perform and/or support one or more functions in the semiconductor device, such as memory (e.g., dynamic random access memory (DRAM)), charge decoupling, analog-to-digital (A/D) conversion, and/or other functions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor device described herein.

FIGS. 2A-2E are diagrams of an example implementation of forming a semiconductor device described herein.

FIGS. 3A-3P are diagrams of an example implementation of forming a trench capacitor structure described herein.

FIG. 4 is a flowchart of an example process associated with forming a semiconductor device described herein.

FIG. 5 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in the semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure.

The trench of a DTC structure is typically formed to have a high aspect ratio between the depth of the trench and the width of the trench. However, forming high aspect ratio trenches for DTC structures by etching is difficult and can suffer from challenges such as controlling the width of the trench (resulting in critical dimension (CD) widening) and corner rounding at the top of the trench because of etching that occurs at the top of the trench. These challenges can lead to increased width of the DTC structure and reduced density of DTC structures in a semiconductor device, among other examples.

In some implementations described herein, a trench for a trench capacitor structure (e.g., a DTC structure) is formed using a metal-containing masking layer. The metal-containing masking layer enables the layers of a semiconductor device to be etched to form the trench in a manner that reduces and/or minimizes corner rounding at the top of the trench. In particular, the metal-containing masking layer suppresses etching in the corners at the top of the trench in that the metal masking-containing layer can be used for multiple etch operations and does not need to be removed between etch operations because of contamination concerns. This enables the metal-containing masking layer to be used to fully form the trench to a bottom contact, where other types of masking layers may have to be removed.

In this way, the metal-containing masking layer protects the top of the trench from corner rounding and enables enhanced critical dimension control at the top of the trench, enabling a high aspect ratio to be achieved for the trench with minimal to no corner rounding. The lesser amount of corner rounding and higher aspect ratio enables the trench capacitor structure to be formed smaller (e.g., with a smaller top width or critical dimension) while achieving a similar capacitance, and/or enables the capacitance of the trench capacitor structure to be increased. In particular, the lesser amount of corner rounding reduces divergence of the MIM layers of the trench capacitor structure at the top of the trench, thereby achieving greater utilization of the area in the trench, which increases the capacitance of the trench capacitor structure.

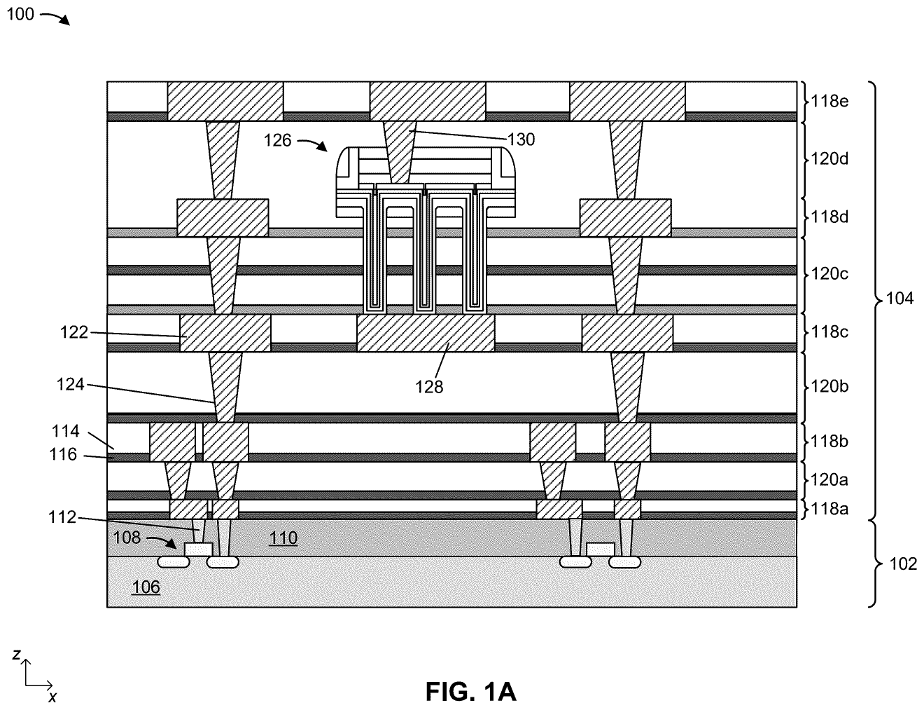

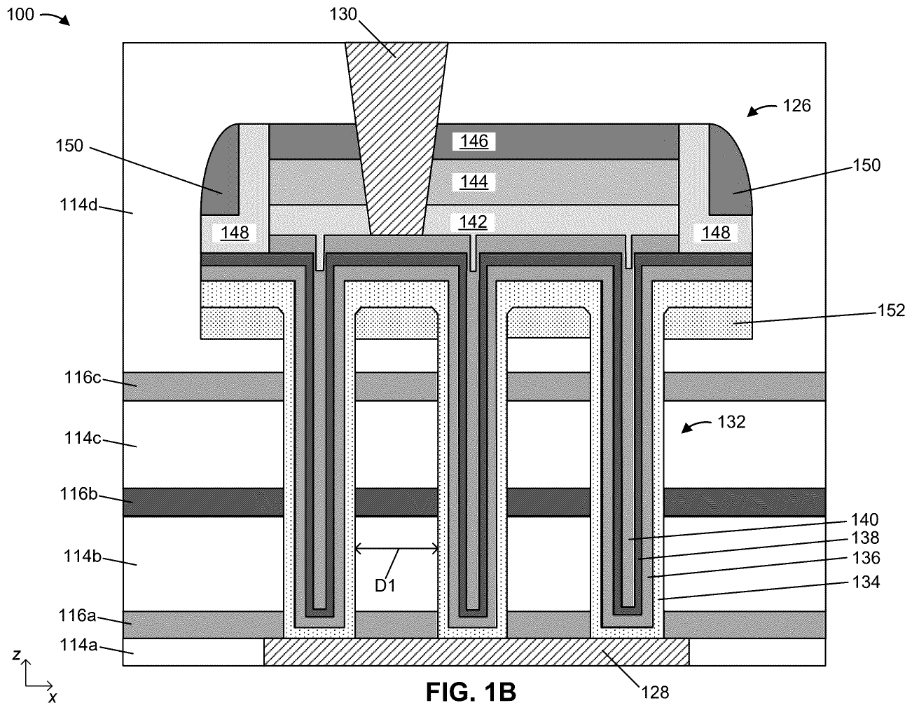

FIGS. 1A and 1B are diagrams of an example semiconductor device 100 described

herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1A illustrates a cross-section view of the semiconductor device 100. As shown in FIG. 1A, the semiconductor device 100 may include a device layer 102 and an interconnect layer 104 arranged in a z-direction in the semiconductor device 100 the device layer 102. For example, the interconnect layer 104 may be located above the device layer 102. As another example, the interconnect layer 104 may be located below the device layer 102.

The device layer 102 may also be referred to as a front end region or front end of line (FEOL) region of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC). Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118d that are vertically arranged and alternate with a plurality of layers 120a-120c in the z-direction (e.g., vertically alternate). The layers 118a-118d each include a layer of metallization structures 122, and the layers 120a-120c each include a layer of interconnect structures 124.

The layers 118a-118d of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO”-layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the a layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, a trench capacitor structure 126 is included in the interconnect layer 104 of the semiconductor device 100. The trench capacitor structure 126 may extend through and/or may be included in one or more dielectric layers in the interconnect layer 104, such as one or more ILD layers 114 and/or one or more ESLs 116. In some implementations, an integrated circuit device 108 is electrically coupled to a trench capacitor structure 126 to form a memory cell (e.g., a dynamic random access memory (DRAM) cell or another type of capacitor-based memory cell) in the semiconductor device 100. In some implementations, a trench capacitor structure 126 is configured to provide charge decoupling for one or more integrated circuit devices 108. In some implementations, a trench capacitor structure 126 is configured to store a charge (e.g., a photocurrent) for an integrated circuit device 108 (e.g., a pixel sensor) in the semiconductor device 100. In some implementations, a trench capacitor structure 126 is configured to perform another function in the semiconductor device 100.

The trench capacitor structure 126 may be electrically coupled and/or physically coupled to a bottom contact 128 at a bottom of the trench capacitor structure 126, and to a top contact 130 at a top of the trench capacitor structure 126. Alternatively, the trench capacitor structure 126 may be electrically coupled and/or physically coupled to a plurality of top contacts at the top of the trench capacitor structure 126. The bottom contact 128 and the top contact 130 may each include one or more conductive structures in the interconnect layer 104, such as one or more metallization structures 122 and/or one or more interconnect structures 124, among other examples.

FIG. 1B illustrates a detailed cross-section view of the trench capacitor structure 126. As shown in FIG. 1B, the trench capacitor structure 126 includes one or more trenches 132 on the bottom contact 128. The bottom contact 128 may be included in an ILD layer 114a in the interconnect layer 104 of the semiconductor device 100. A trench 132 of the trench capacitor structure 126 may extend through one or more dielectric layers in the interconnect layer 104 of the semiconductor device 100, including through an ESL 116a, an ILD layer 114a, an ESL 116b, an ILD layer 114c, an ESL 116c, and/or an ILD layer 114d, among other examples. In some implementations, the trench(es) 132 may have a high aspect ratio, which is a ratio of a depth (or height) of the trench(es) 132 to a lateral width (or critical dimension) of the trench(es) 132. Thus, the trench capacitor structure 126 may be referred to as a DTC structure. In some implementations, the aspect ratio of a trench 132 may be approximately 10:1 or greater. In some implementations, a trench 132 may have an aspect ratio that is included in the range of approximately 20:1 to approximately 50:1. However, other values and ranges are within the scope of the present disclosure.

As further shown in FIG. 1B, the trench capacitor structure 126 includes a plurality of conformal layers that conform to the profile of the trench(es) 132. The conformal layers may include an adhesion layer 134, a bottom electrode layer 136 on the adhesion layer 134, and an insulator layer 138 on the bottom electrode layer 136. The adhesion layer 134, the bottom electrode layer 136, and the insulator layer 138 may each conform to the profile of the trench(es) 132 such that the adhesion layer 134, the bottom electrode layer 136, and the insulator layer 138 conform to the sidewalls and the bottom surfaces of the trench(es) 132. The trench capacitor structure 126 further includes a top electrode layer 140 on the insulator layer 138. In some implementations, the top electrode layer 140 is a fill layer that fills in the remaining areas of the trench(es) 132. Alternatively, the top electrode layer 140 may also be a conformal layer that conforms to the sidewalls and the bottom surfaces of the trench(e) 132, and a dielectric plug layer or fill layer is further included in the remaining areas of the trench(es) 132.

The adhesion layer 134 may also be referred to as a glue layer, and may be included to promote adhesion of the bottom electrode layer 136 to the dielectric layers (e.g., the ILD layers 114b, 114c, and 114d, the ESLs 116a, 116b, and 116c) and/or to the bottom contact 128. The adhesion layer 134 may include tantalum (Ta), tantalum nitride (TaN), and/or another suitable adhesion material.

The bottom electrode layer 136, the insulator layer 138, and the top electrode layer 140 correspond to an MIM structure of the trench capacitor structure 126. Thus, the trench capacitor structure 126 may also be referred to as an MIM capacitor structure. The bottom electrode layer 136 (also referred to as a capacitor bottom metal (CBM)) and the top electrode layer 140 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 136 and the top electrode layer 140 include the same material or the same material composition. In some implementations, the bottom electrode layer 136 and the top electrode layer 140 include different materials or different material compositions.

The insulator layer 138 may include one or more electrically insulating materials. In some implementations, the insulator layer 138 includes one or more low-k dielectric materials such as silicon oxide (SiOₓ such as SiO₂). Additionally and/or alternatively, the insulator layer 138 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 138 is a multiple-layer stack that includes a plurality of dielectric layers. For example, the insulator layer 138 may include a ZrO₂/Al₂O₃/ZrO₂ (ZAZ) layer stack.

In some implementations, the trench capacitor structure 126 includes a plurality of trenches 132, and the MIM structure of the trench capacitor structure 126 (e.g., the bottom electrode layer 136, the insulator layer 138, and the top electrode layer 140) may extend along the sidewalls and bottom surfaces of the plurality of trenches 132, and between the plurality of trenches 132. The trenches 132 may be laterally arranged and spaced apart by a distance (indicated in FIG. 1B as dimension D1) in the x-direction. In this way, including a plurality of trenches 132 in the trench capacitor structure 126 enables the length (and therefore the area) of the MIM structure of the trench capacitor structure 126 (e.g., of the bottom electrode layer 136, the insulator layer 138, and the top electrode layer 140) to be extended, thereby increasing the capacitance of the trench capacitor structure 126.

As further shown in FIG. 1B, the trench capacitor structure 126 may include one or more capping layers above the trench(es) 132 and above the MIM structure of the trench capacitor structure 126. The one or more capping layers may include an oxide capping layer 142, an oxynitride capping layer 144, and/or a nitride capping layer 146, among other examples. The capping layers may provide electrical isolation for the MIM structure of the trench capacitor structure 126, and/or may also function as a hard mask layer stack for forming the top contact 130. The oxide capping layer 142 may include an oxide-containing dielectric material such as silicon oxide (SiOₓ such as SiO₂), among other examples. The oxynitride capping layer 144 may include an oxynitride-containing dielectric material such as silicon oxynitride (SiON), among other examples. The nitride capping layer 146 may include a nitride-containing dielectric material such as silicon nitride (SiₓN_{y} such as Si₃N₄), among other examples.

As further shown in FIG. 1B, the trench capacitor structure 126 may include one or more sidewall spacers 148 and/or 150 on the sidewalls of the capping layers 142-146 and/or on sidewalls of the top electrode layer 140 that is above the trench(es) 132. The combination of the capping layers 142-146 and the sidewall spacers 148 and 150 may be used as a self-aligned mask when etching the adhesion layer 134, the bottom electrode layer 136, the insulator layer 138, and/or the top electrode layer 140 to define the MIM structure of the trench capacitor structure 126. The sidewall spacer 148 may include an oxide-containing dielectric material such as silicon oxide (SiOₓ such as SiO₂), among other examples. The sidewall spacer 150 may include a nitride-containing dielectric material such as silicon nitride (SiₓN_{y} such as Si₃N₄), among other examples.

As further shown in FIG. 1B, the trench capacitor structure 126 includes a metal-containing layer 152. The metal-containing layer 152 may include a plurality of segments that are laterally adjacent to opposing sides of the trenches 132. Thus, the segments of the metal-containing layer 152 may be included between laterally adjacent trenches 132 of the trench capacitor structure 126. The adhesion layer 134, the bottom electrode layer 136, the insulator layer 138, and/or the top electrode layer 140 may continuously extend over the metal-containing layer 152 between the trenches 132.

The metal-containing layer 152 is located at the tops of the trenches 132 and under portions of the adhesion layer 134 at the tops of the trenches 132. The portions of the bottom electrode layer 136, the portions of the insulator layer 138, and the portions of the top electrode layer 140 that span the spaces between the trenches 132 may also be located on and/or above the metal-containing layer 152. The adhesion layer 134 may electrically isolate the bottom electrode layer 136 from the metal-containing layer 152.

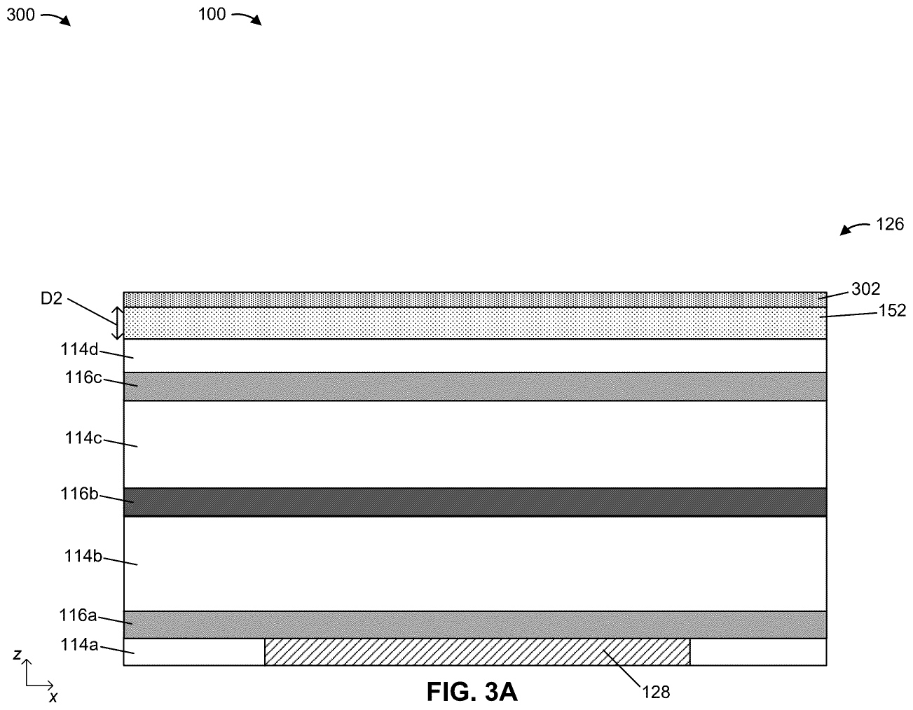

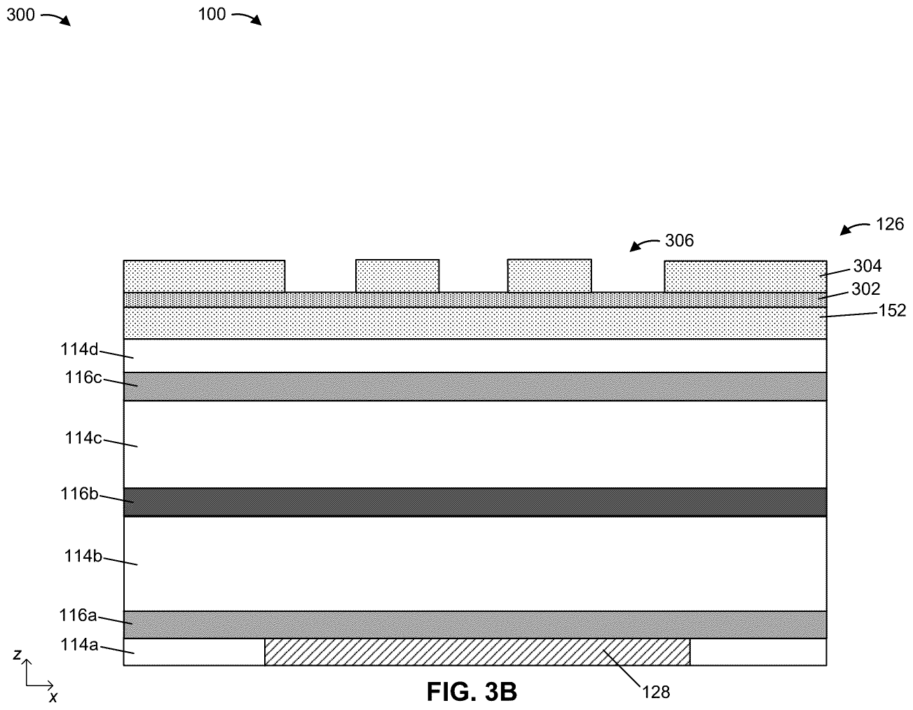

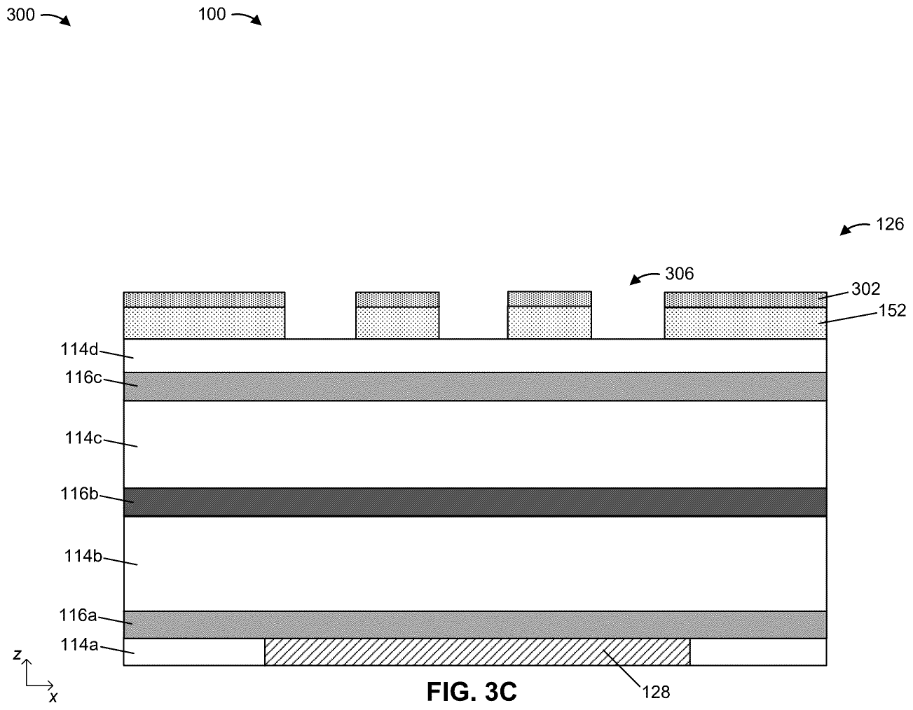

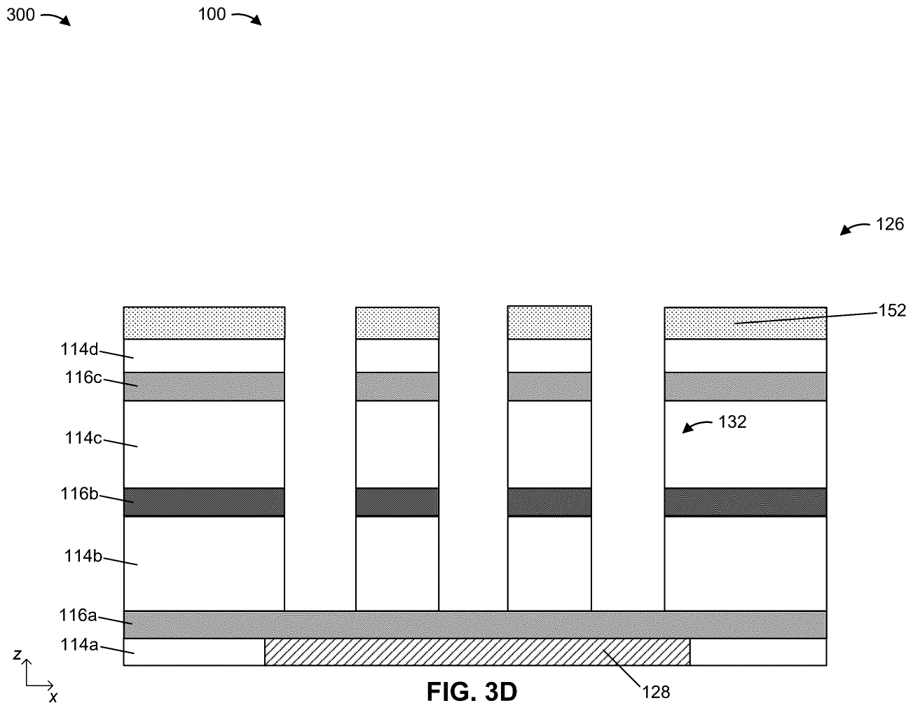

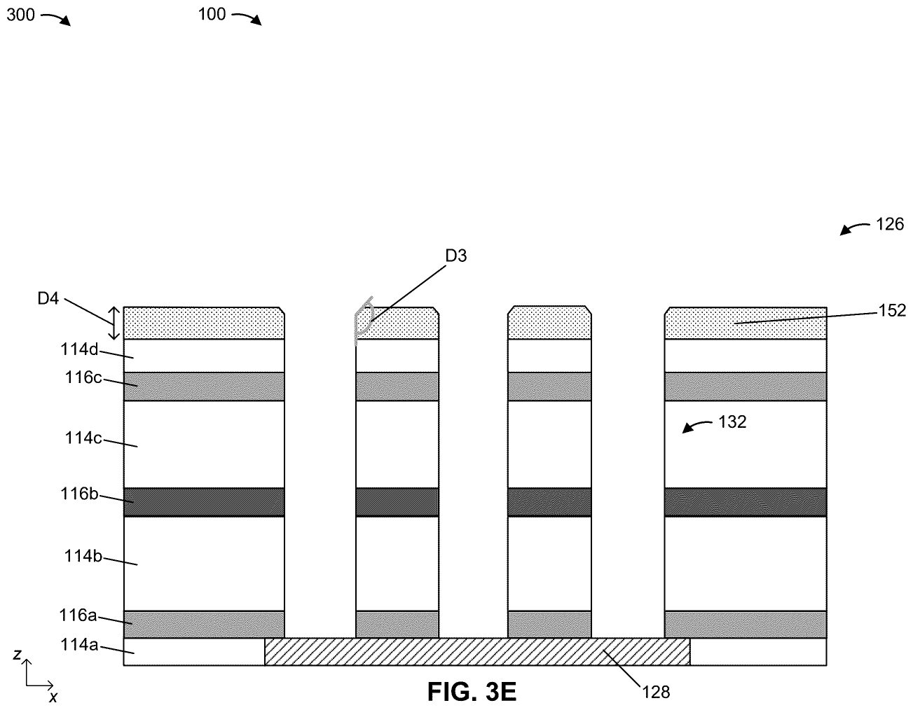

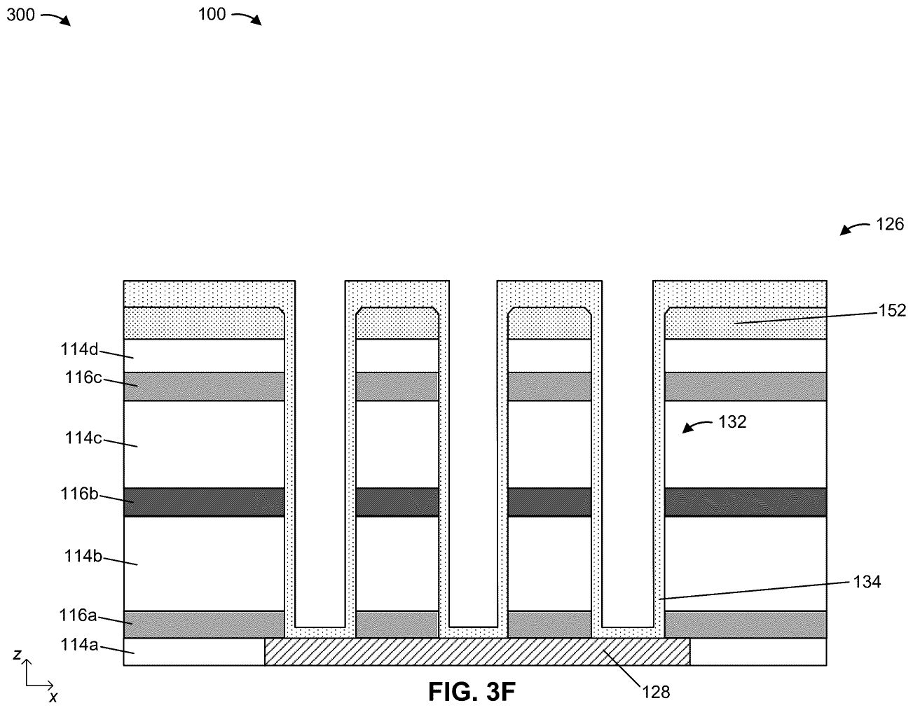

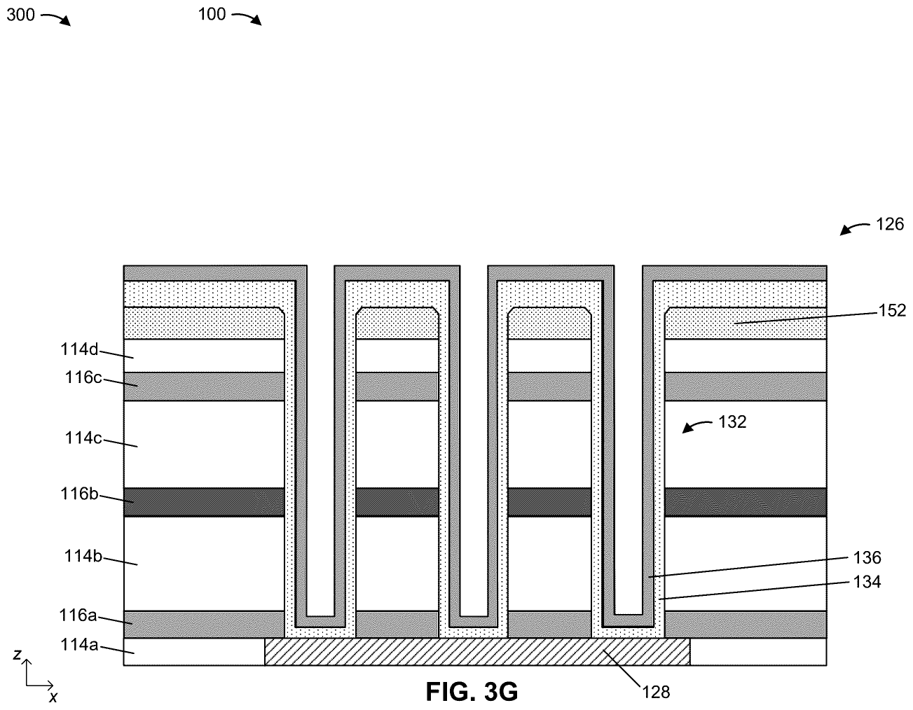

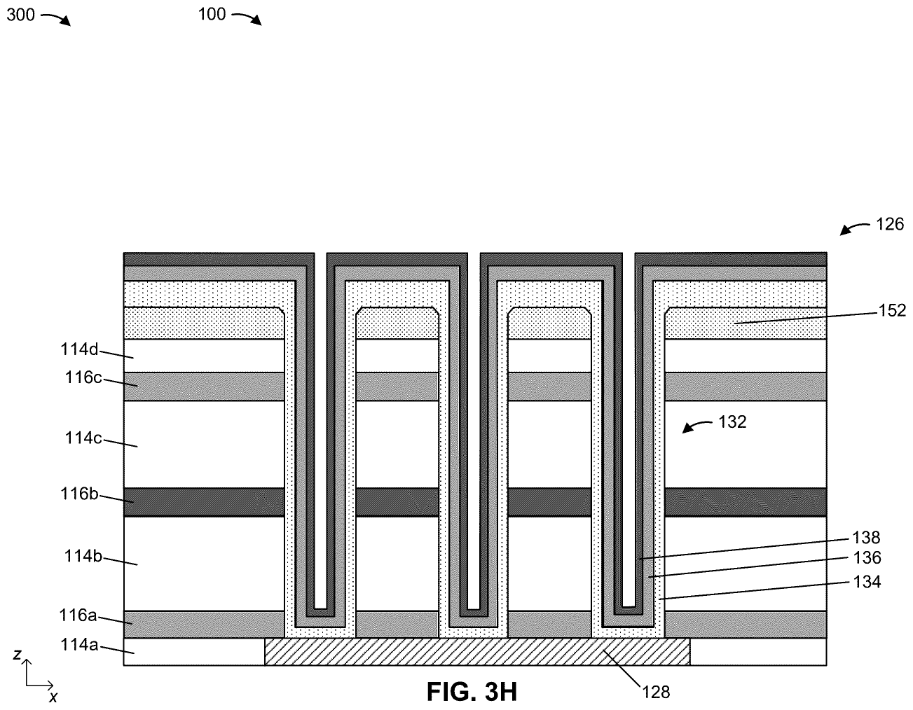

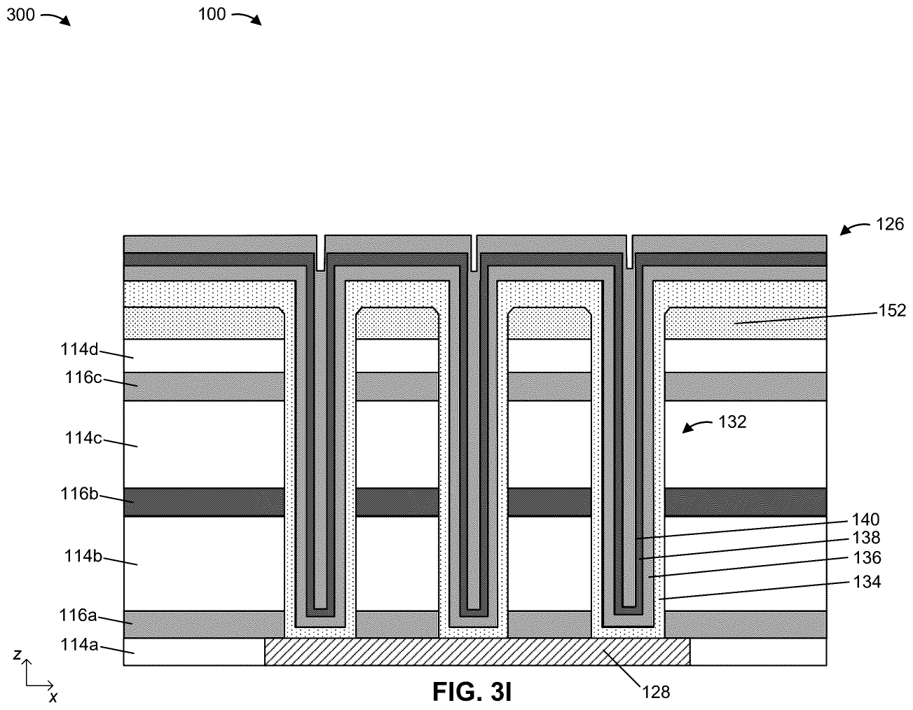

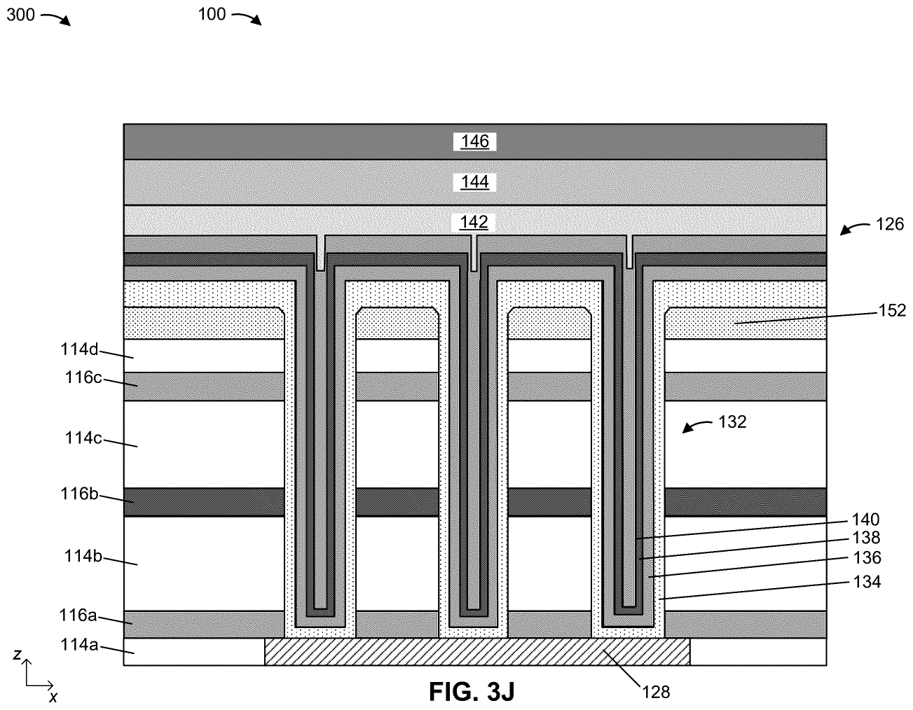

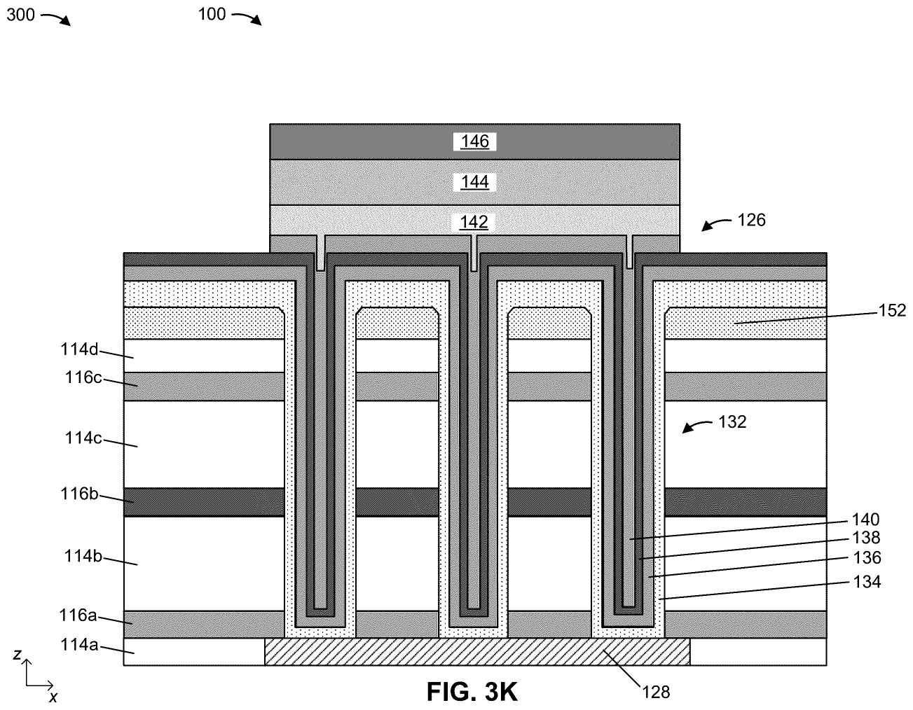

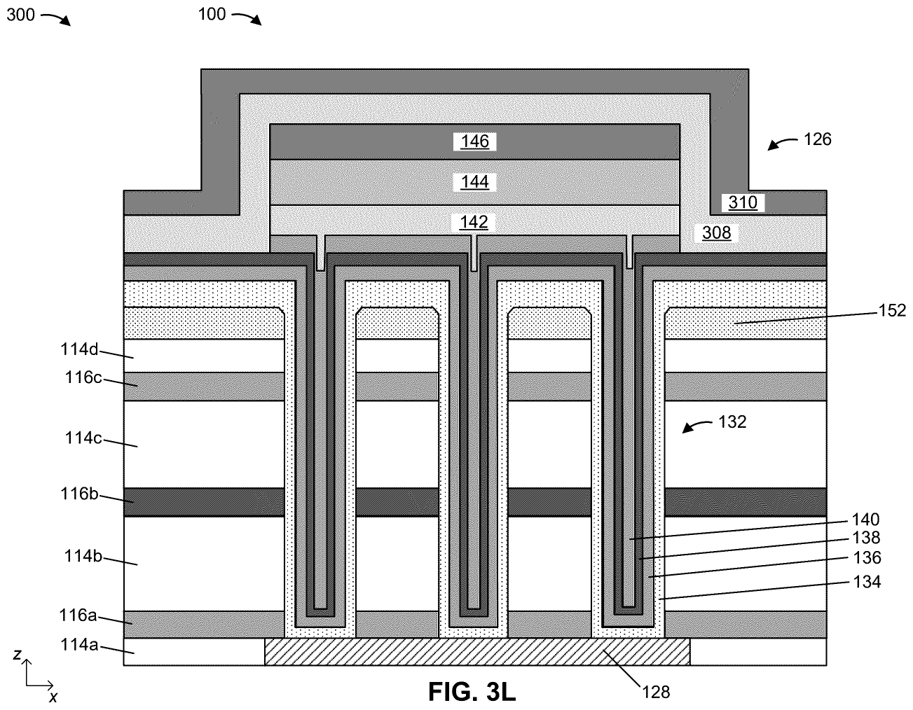

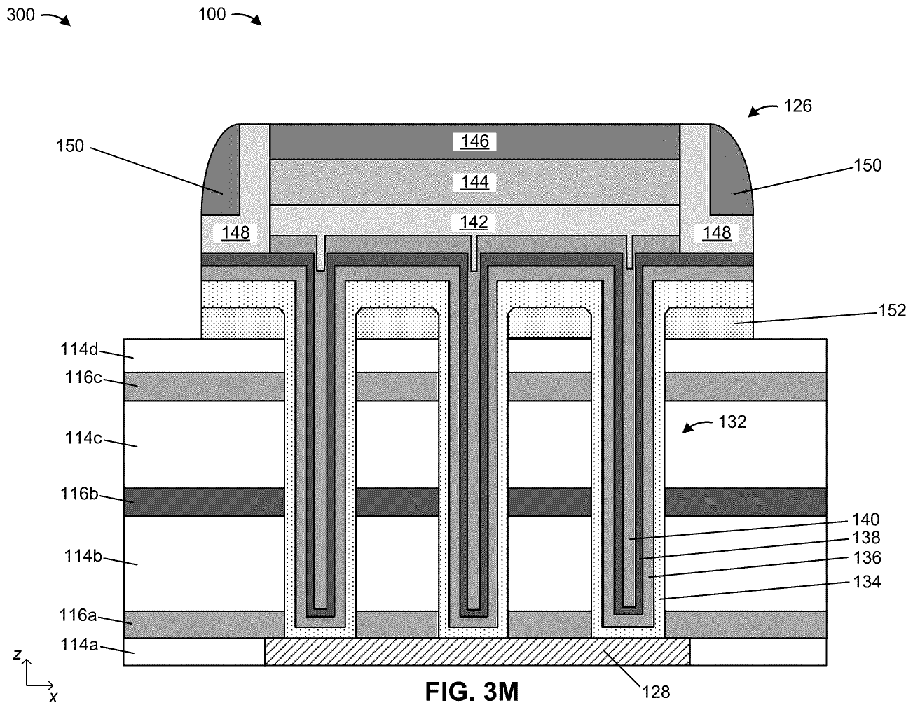

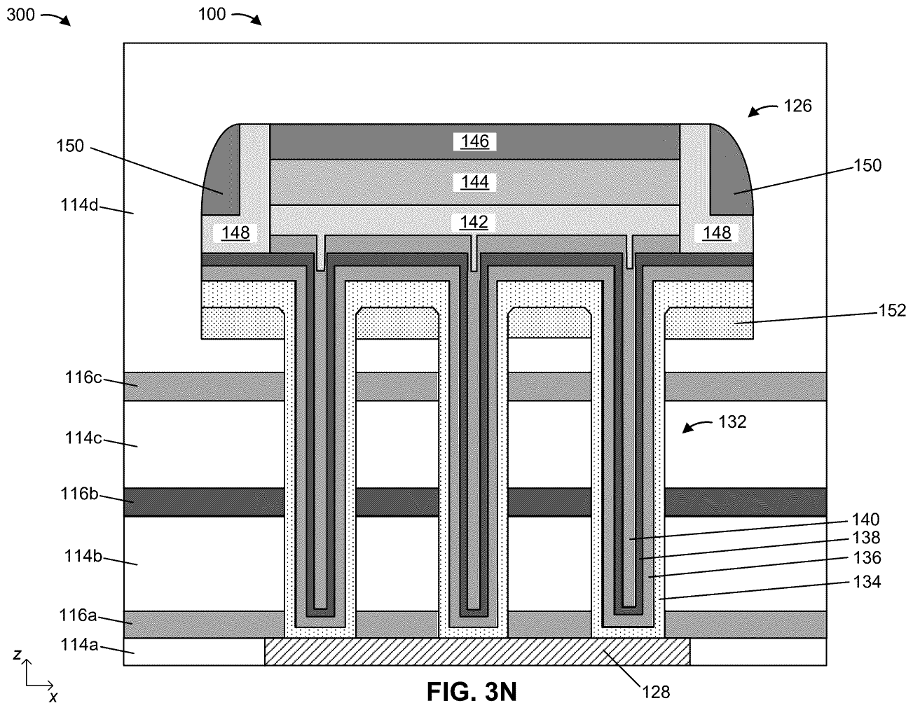

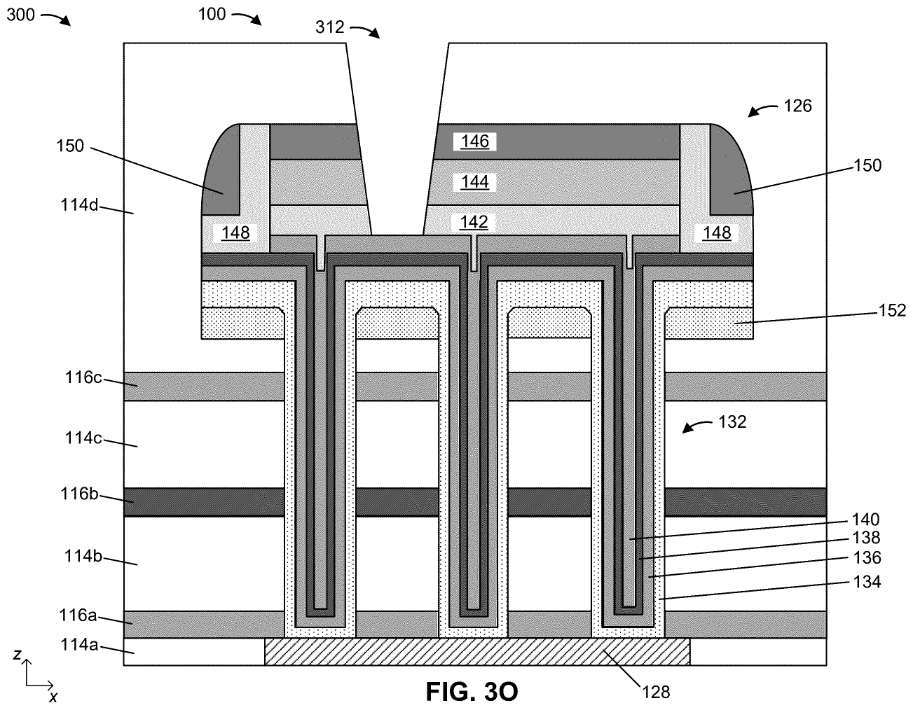

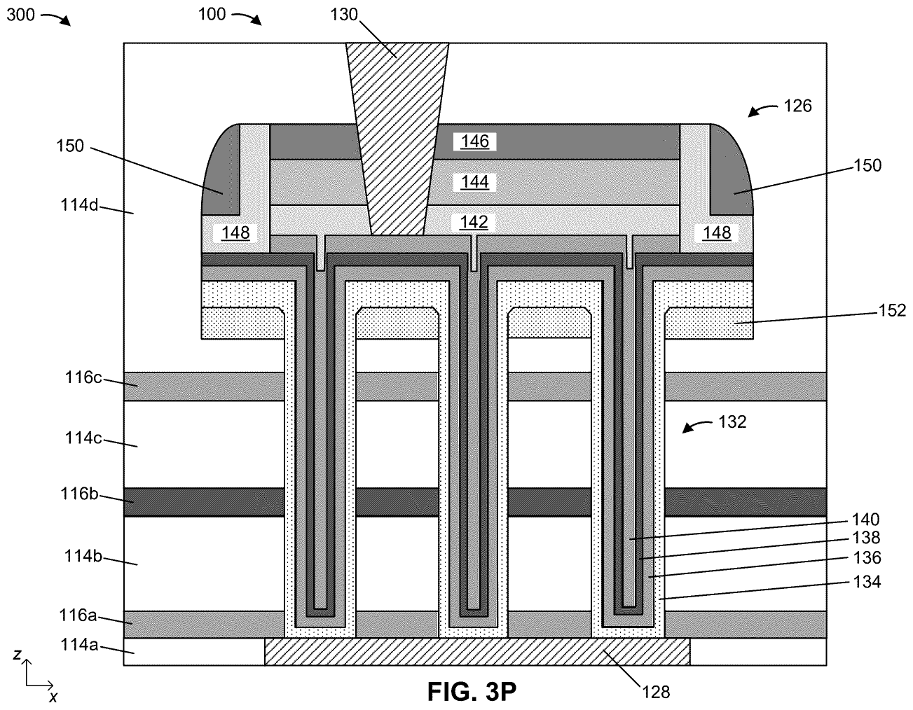

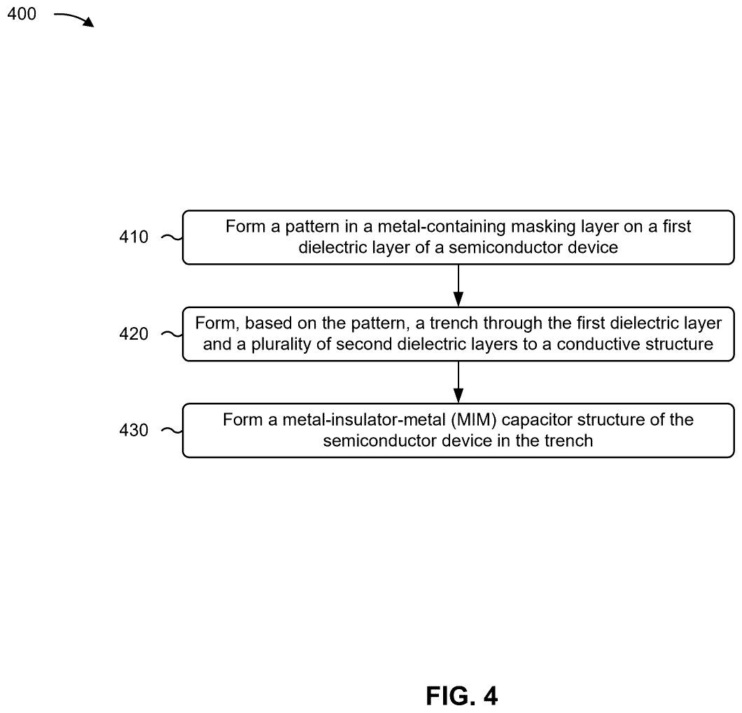

The metal-containing layer 152 is included in the trench capacitor structure 126 as a masking layer that is used to etch the ILD layers 114b, 114c, 114d and the ESLs 116a, 116b, 116c to form the trenches 132 of the trench capacitor structure 126. The metal-containing layer 152 may remain in the trench capacitor structure 126 after formation of the trenches 132 in that the metal-containing layer 152 does not pose a risk of carbon (C), oxygen (O), and/or hydrogen (H) contamination to the trench capacitor structure 126 and/or to other layers and/or structures in the semiconductor device 100 because the metal-containing layer 152 experiences minimal to no breakdown over time (and thus, minimal to no release of organic contaminants). In this way, retaining the metal-containing layer 152 in the trench capacitor structure 126 reduces the cost, time and/or complexity of forming the trench capacitor structure 126 in that the trench capacitor structure 126 can be formed by fewer processing operations because a masking layer ashing operation may be omitted for the metal-containing layer 152. The use of the metal-containing layer 152 as a metal-containing masking layer for forming the trenches 132 is described in connection with FIGS. 3A-3P, 4, and/or 5, among other examples.

As further shown in FIG. 1B, the ends of the metal-containing layer 152 are approximately vertically aligned with the ends of the adhesion layer 134, the ends of the bottom electrode layer 136, and the ends of the insulator layer 138. This may occur, for example, because of the metal-containing layer 152 being etched in the same etch operation along with the adhesion layer 134, the bottom electrode layer 136, and the insulator layer 138 to define the MIM structure of the trench capacitor structure 126. The etch operation may be referred to as a CBM etch operation. The metal-containing layer 152 may be etched in the CBM etch operation to reduce the likelihood of electrical shorting of other structures and/or layers to the metal-containing layer 152.

The metal-containing layer 152 may include one or more metals such as tungsten (W), cobalt (Co), ruthenium (Ru), titanium (Ti), aluminum (Al), copper (Cu), and/or gold (Au), among other examples. In some implementations, the metal-containing layer 152 includes a metal-nitride material such as a titanium nitride (TiN) material and/or a tantalum nitride (TaN) material, among other examples. In some implementations, the metal-containing layer 152 includes a metal-carbide material such as a tungsten carbide (WC) material, among other examples.

As indicated above, FIGS. 1A and 1B are provided as an example. Other examples may differ from what is described with regard to FIGS. 1A and 1B.

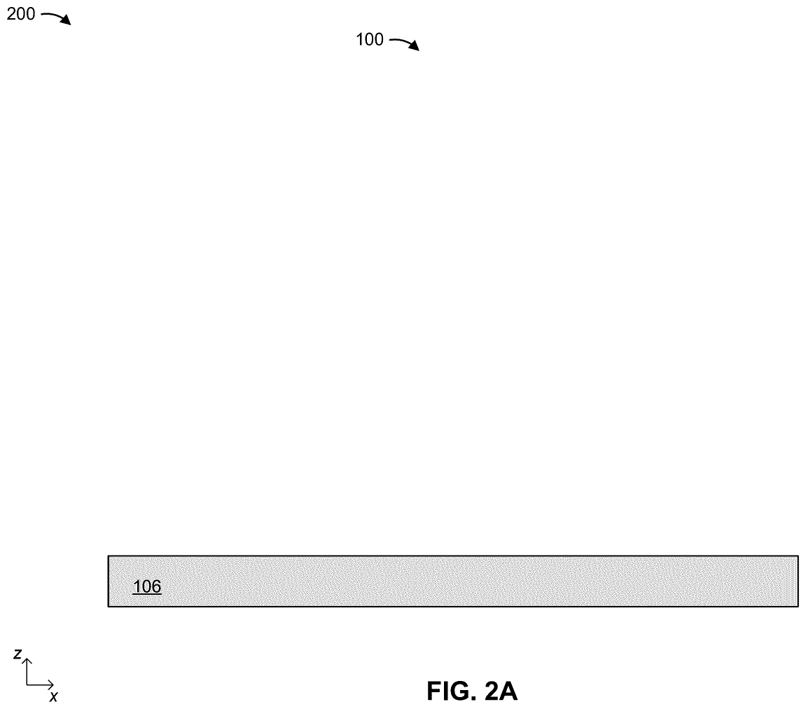

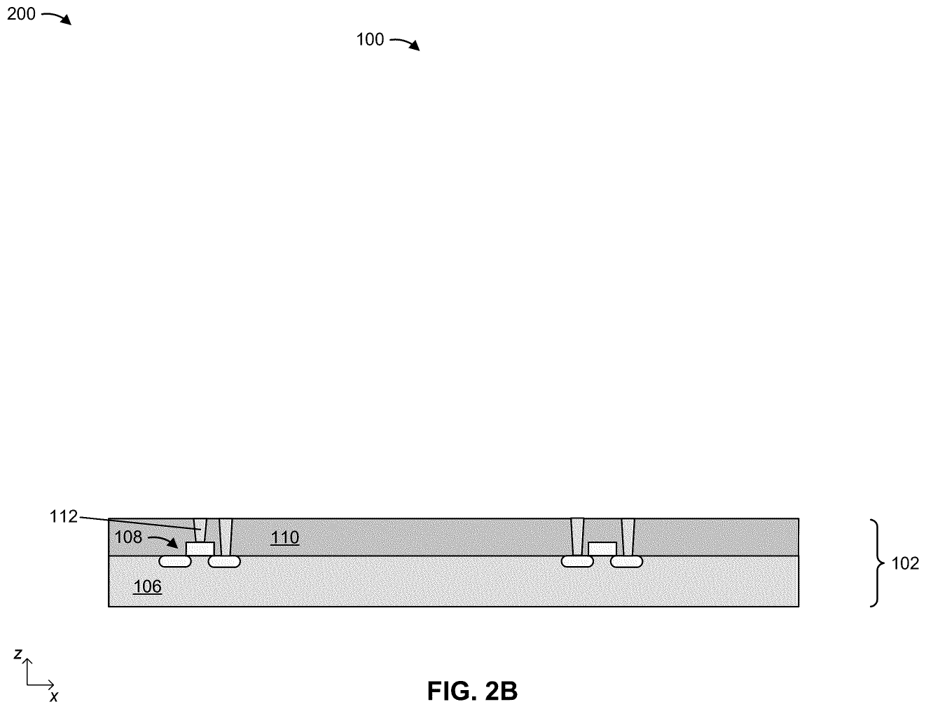

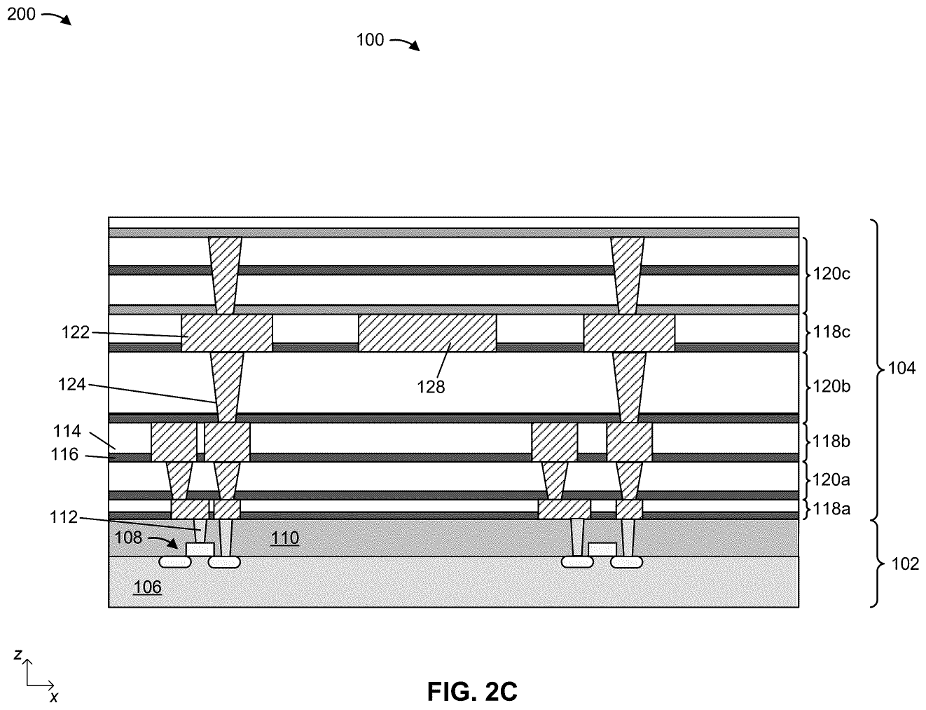

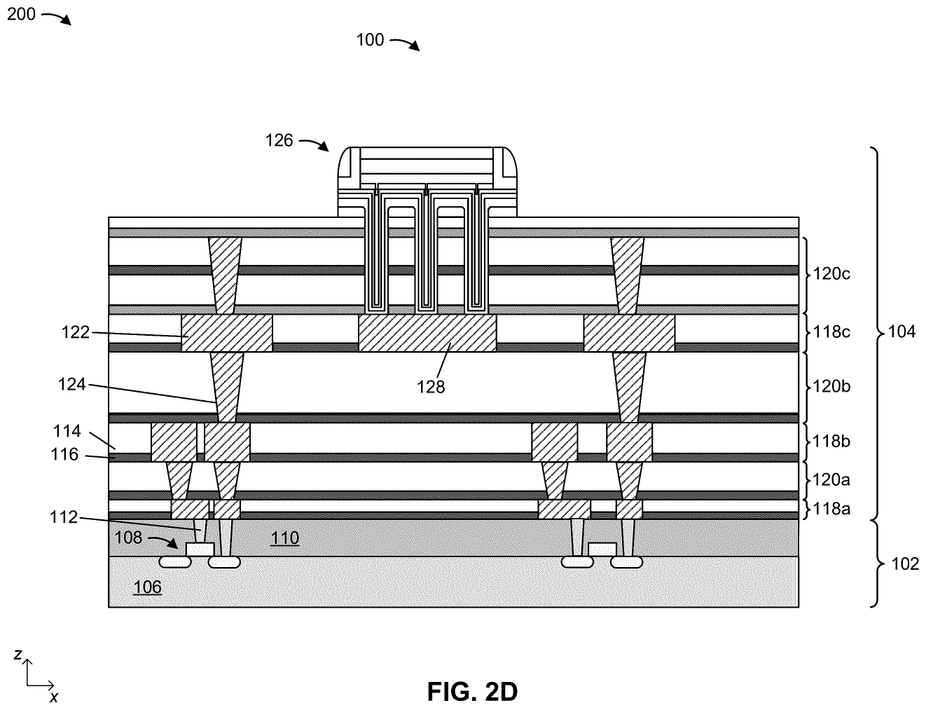

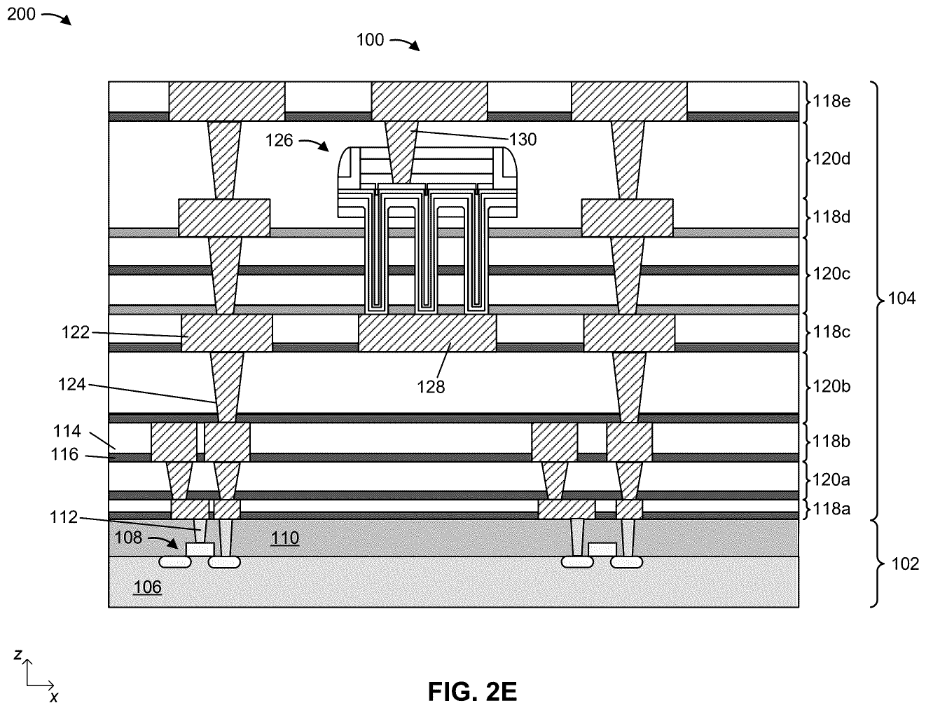

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIGS. 2C, a deposition tool, an exposure tool, a developer tool, an etch tool, a planarization tool, a plating tool, and/or another semiconductor processing tool may be used to perform various operations to form the metallization structures 122 and to form the interconnect structures 124 in the first portion of the interconnect layer 104 of the semiconductor device 100. The bottom contact 128 of the trench capacitor structure 126 may also be formed in the first portion of the interconnect layer 104.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b, 118c, 120b, and 120c may be formed in a similar manner.

One or more deposition tools may be used to deposit the metallization structures 122, the interconnect structures 124, and/or the bottom contact 128 using a PVD technique, an ALD technique, a CVD technique, an electroplating technique (e.g., an electro-chemical plating technique), and/or another suitable deposition technique. In some implementations, a planarization tool may be used to planarize the metallization structures 122, the interconnect structures 124, and/or the bottom contact 128 after the metallization structures 122, the interconnect structures 124, and/or the bottom contact 128 are deposited.

As shown in FIG. 2D, a trench capacitor structure 126 may be formed in one or more dielectric layers in the interconnect layer 104. The trench capacitor structure 126 may be formed such that the trench(es) 132 of the trench capacitor structure 126 land on the bottom contact 128 in the interconnect layer 104. An example process for forming the trench capacitor structure 126 is illustrated and described in connection with FIGS. 3A-3P.

As shown in FIG. 2E, a second portion of the interconnect layer 104 of the semiconductor device 100 is formed above the first portion of the interconnect layer 104, including above the trench capacitor structure 126. The second portion of the interconnect layer 104 may be formed in a similar manner as the first portion of the interconnect layer 104 as described in connection with FIG. 2C. The top contact 130 of the trench capacitor structure 126 may be formed in the second portion of the interconnect layer 104.

As indicated above, FIGS. 2A-2E are provided as an example. Other examples may differ from what is described with regard to FIGS. 2A-2E.

FIGS. 3A-3P are diagrams of an example implementation 300 of forming a trench capacitor structure 126 described herein. In some implementations, one or more of the semiconductor processing operations described in connection with FIGS. 3A-3P may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 3A-3P may be performed as part of the process for forming the semiconductor device 100 described in connection with FIGS. 2A-2E.

As shown in FIG. 3A, masking layers may be formed on the ILD layer 114d in the interconnect layer 104 of the semiconductor device 100. For example, the metal-containing layer 152 (e.g., a metal-containing masking layer) may be formed on the ILD layer 114d, and a dielectric masking layer 302 may be formed above the ILD layer 114d on the metal-containing layer 152. The dielectric masking layer 302 may include a silicon oxynitride material (SiON) and/or another suitable dielectric material.

A deposition tool may be used to deposit the material of the metal-containing layer 152 using a CVD technique, a PVD technique, an ALD technique, an electroplating technique, and/or another suitable deposition technique. In some implementations, a planarization tool is used to perform a planarization operation (e.g., a CMP operation) to planarize the metal-containing layer 152 after the metal-containing layer 152 is deposited. A deposition tool may be used to deposit the dielectric masking layer 302 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 302 after the dielectric masking layer 302 is deposited.

The metal-containing layer 152 may be formed to a thickness (indicated in FIG. 3A as a dimension D2) that is included in a range of approximately 400 angstroms to approximately 600 angstroms. If the thickness of the metal-containing layer 152 is less than approximately 400 angstroms, the metal-containing layer 152 may be susceptible to being etched through when the trench(es) 132 of the trench capacitor structure 126 are formed, resulting in etching into the underlying ILD layer 114d. Thicknesses of greater than approximately 600 angstroms for the metal-containing layer 152 may result in reduced control over the width or critical dimension of the trench(es) 132, and may also result in under etching of the metal-containing layer 152 in a subsequent CBM etch operation to define the MIM structure of the trench capacitor structure 126. If the thickness of the metal-containing layer 152 is included in the range of approximately 400 angstroms to approximately 600 angstroms, sufficient control over the width or critical dimension of the trench(es) 132 may be achieved with reduced likelihood of etching through the metal-containing layer 152 when forming the trench(es) 132. However, other values for the thickness of the metal-containing layer 152, and ranges other than approximately 400 angstroms to approximately 600 angstroms, are within the scope of the present disclosure.

As shown in FIG. 3B, a photoresist layer 304 may be formed above the metal-containing layer 152 and the dielectric masking layer 302, and a pattern 306 may be formed in the photoresist layer 304. A deposition tool may be used to form the photoresist layer on the dielectric masking layer 302 (e.g., using a spin-coating technique or another suitable deposition technique). In some implementations, a bottom antireflective coating (BARC) is first deposited on the dielectric masking layer 302, and then the photoresist layer 304 is deposited onto the BARC. An exposure tool may be used to expose the photoresist layer 304 to a radiation source to pattern the photoresist layer 304. A developer tool may be used to develop and remove portions of the photoresist layer 304 to expose the pattern 306.

As shown in FIG. 3C, an etch tool may be used to etch the dielectric masking layer 302 and the metal-containing layer 152 based on the pattern 306 in the photoresist layer 304, to transfer the pattern 306 to the dielectric masking layer 302 and the metal-containing layer 152. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

In some implementations, the etch operation includes a gas-based etch operation in which a chlorine-based etchant is used to transfer the pattern 306 to the metal-containing layer 152. The chlorine-based etchant may include a chlorine-based (Clₓ) gas (e.g., a Cl₂ gas) etchant. The chlorine-based gas etchant may have a higher etch rate for the metal-containing layer 152 compared to the dielectric material of the underlying ILD layer 114d. Thus, the gas-based etch operation may stop on the ILD layer 114d with minimal etching to the ILD layer 114d.

As shown in FIG. 3D, another etch operation is performed to etch through the ILD layers 114b, 114c, 114d, and through the ESLs 116b and 116c to form the trench(es) 132 of the trench capacitor structure 126. The etch operation may include another gas-based etch operation in which a different type of gas-based etchant is used compared to the gas-based etchant that was used to transfer the pattern 306 to the metal-containing layer 152. Thus, the semiconductor device 100 may be transferred from a first etch tool (in which the pattern 306 was transferred to the metal-containing layer 152) to a second etch tool (in which the ILD layers 114b, 114c, 114d, and the ESLs 116b and 116c are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of gas-base etchants.

The gas-based etchant that is used to etch the ILD layers 114b, 114c, 114d, and the ESLs 116b, 116c, may include a fluorine-based gas etchant that has a higher etch rate for the dielectric materials of the ILD layers 114b, 114c, 114d, and the ESLs 116b, 116c, compared to the etch rate of the metal-containing layer 152. This enables the ILD layers 114b, 114c, 114d, and the ESLs 116b, 116c, to be etched with minimal etching to the metal-containing layer 152 (and thus, minimal to no increase in the width or critical dimension at the tops of the trench(es) 132). The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the trench(es) 132 of the trench capacitor structure 126. For example, a first etch operation (referred to as a “main etch” operation) may performed to form the trench(es) 132 to the ESL 116a. In other words, etching in the first etch operation stops at the ESL 116a such that the ESL 116a remains between the bottom of the trench(es) 132 and the underlying bottom contact 128. The ESL 116a is kept over the bottom contact 128 to prevent the bottom contact 128 from being exposed to oxygen and other contaminants that might otherwise result in oxidation of the bottom contact 128. After the first etch operation, the trench(es) 132 may have tapered sidewalls, resulting in the lateral width of the trench(es) 132 decreasing from the tops of the trench(es) 132 to the bottoms of the trenches.

A second etch operation (referred to as an “over etch” operation) may be performed after the first etch operation to shape the bottom portions of the trench(es) 132. In particular, the second etch operation may be performed to increase the verticality of the sidewalls of the trench(es) 132, thereby lessening the taper in the sidewalls of the trench(es) 132. The metal-containing layer 152 remains on the ILD layer 114d during the first and second etch operations to form and shape the trench(es) 132 such that the metal-containing layer 152 protects the ILD layer 114d from being etched, which reduces the likelihood of critical dimension widening and reduces the likelihood of corner rounding at the tops of the trench(es) 132.

As shown in FIG. 3E, a third etch operation (referred to as a “linear removal” etch operation) is performed to etch through the ESL 116a at the bottom the trench(es) 132 to extend the trench(es) 132 through the ESL 116a and to the underlying bottom contact 128. Thus, the bottom contact 128 is exposed through the trench(es) 132 after the third etch operation. The third etch operation may be performed using the second etch tool and using a fluorine-based etchant may such as a carbon fluoride-based (CFₓ such as CF₄) gas etchant.

The metal-containing layer 152 remains on the ILD layer 114d during the third etch operation to etch through the ESL 116a such that the metal-containing layer 152 protects the ILD layer 114d from being etched, which reduces the likelihood of critical dimension widening and reduces the likelihood of and/or amount of corner rounding at the tops of the trench(es) 132. For example, the tops of the trench(es) 132 may have rounded edges, and an angle (indicated in FIG. 3E as dimension D3) of a rounded edge of a trench 132 relative to a sidewall of a trench 132 may be included in a range of approximately 100 degrees to approximately 110 degrees, whereas the angle might otherwise be approximately 130 degrees or greater without the use of the metal-containing layer 152 when forming the trench(es) 132. However, other values and ranges are within the scope of the present disclosure.

As further shown in FIG. 3E, the thickness of the metal-containing layer 152 (indicated in FIG. 3E as dimension D4) after forming the trench(es) 132 is included in a range of approximately 150 angstroms to approximately 350 angstroms. In other words, the thickness of the metal-containing layer 152 in the trench capacitor structure 126 is less than the as-formed thickness of the metal-containing layer 152 in that some of the metal-containing layer 152 is consumed during formation of the trench(es) 132.

As shown in FIG. 3F, the adhesion layer 134 may be deposited on the sidewalls and on the bottom surfaces of the trench(es) 132. The bottom surfaces of the trench(es) 132 correspond to the top surface of the bottom contact 128, and thus the adhesion layer 134 may be in physical contact with the top surface of the bottom contact 128. The adhesion layer 134 may also be deposited on the top surface of the metal-containing layer 152 between adjacent trenches 132 such that the adhesion layer 134 may be in physical contact with the top surface of the metal-containing layer 152. In some implementations, a deposition tool is used to conformally deposit the adhesion layer 134 such that the adhesion layer 134 conforms to the profile of the trench(es) 132. In some implementations, a conformal CVD technique and/or an ALD technique is used to deposit the adhesion layer 134.

As shown in FIG. 3G, the bottom electrode layer 136 may be deposited on the adhesion layer 134. Thus, the bottom electrode layer 136 is deposited on the sidewalls and on the bottom surfaces (which correspond to the top surface of the bottom contact 128) of the trench(es) 132. The bottom electrode layer 136 may also be deposited on the top surface of the metal-containing layer 152 between adjacent trenches 132. In some implementations, a deposition tool is used to conformally deposit the bottom electrode layer 136 such that the bottom electrode layer 136 conforms to the profile of the trench(es) 132. In some implementations, a conformal CVD technique and/or an ALD technique is used to deposit the bottom electrode layer 136.

As shown in FIG. 3H, the insulator layer 138 may be deposited on the bottom electrode layer 136. Thus, the insulator layer 138 is deposited on the sidewalls and on the bottom surfaces (which correspond to the top surface of the bottom contact 128) of the trench(es) 132. The insulator layer 138 may also be deposited on the top surface of the metal-containing layer 152 between adjacent trenches 132. In some implementations, a deposition tool is used to conformally deposit the insulator layer 138 such that the insulator layer 138 conforms to the profile of the trench(es) 132. In some implementations, a conformal CVD technique and/or an ALD technique is used to deposit the insulator layer 138.

As shown in FIG. 3I, the top electrode layer 140 may be deposited on the insulator layer 138. The top electrode layer 140 may be deposited such that the top electrode layer 140 fills the remaining areas of the trench(es) 132. The top electrode layer 140 may also be deposited on the top surface of the metal-containing layer 152 between adjacent trenches 132. In some implementations, a deposition tool is used to conformally deposit the top electrode layer 140 using a PVD technique, a CVD technique, an ALD technique, and/or another suitable deposition technique.

As shown in FIG. 3J, capping layers are formed above the trenches 132 of the trench capacitor structure 126. For example, the oxide capping layer 142 may be formed above and/or on the top electrode layer 140, the oxynitride capping layer 144 may be formed above and/or on the oxide capping layer 142, and/or the nitride capping layer 146 may be formed above and/or on the oxynitride capping layer 144, among other examples.

A deposition tool may be used to deposit the oxide capping layer 142, the oxynitride capping layer 144, and/or the nitride capping layer 146 using a PVD technique, an ALD technique, a CVD technique, an oxidation technique, and/or another suitable deposition technique. The oxide capping layer 142, the oxynitride capping layer 144, and/or the nitride capping layer 146 may be deposited in one or more deposition operations. In some implementations, a planarization tool may be used to perform a planarization operation (e.g., a CMP operation) to planarize the oxide capping layer 142, the oxynitride capping layer 144, and/or the nitride capping layer 146 after the oxide capping layer 142, the oxynitride capping layer 144, and/or the nitride capping layer 146 is deposited.

As shown in FIG. 3K, the capping layers (e.g., the oxide capping layer 142, the oxynitride capping layer 144, and/or the nitride capping layer 146) may be used to etch and define the top electrode layer 140 of the trench capacitor structure 126. In some implementations, a pattern in a photoresist layer is used to etch the oxide capping layer 142, the oxynitride capping layer 144, and/or the nitride capping layer 146 to form a hard mask over the top electrode layer 140. In these implementations, a deposition tool may be used to form the photoresist layer on the nitride capping layer 146. An exposure tool may be used to expose the photoresist layer to a radiation source to pattern the photoresist layer. A developer tool may be used to develop and remove portions of the photoresist layer to expose the pattern. An etch tool may be used to etch the oxide capping layer 142, the oxynitride capping layer 144, and/or the nitride capping layer 146 based on the pattern to define the hard mask layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). An etch tool may then be used to etch the top electrode layer 140 based on the hard mask layer (e.g., based on the pattern in the oxide capping layer 142, the oxynitride capping layer 144, and/or the nitride capping layer 146) to define the top electrode layer 140.

As shown in FIG. 3L, spacer layers 308 and 310 are formed above the capping layers (e.g., the oxide capping layer 142, the oxynitride capping layer 144, and/or the nitride capping layer 146). The spacer layers 308 and 310 extend along the ends of the capping layers (e.g., along the ends of the oxide capping layer 142, the ends of oxynitride capping layer 144, and/or the ends of the nitride capping layer 146) and along the ends of the top electrode layer 140. Moreover, the spacer layers 308 and 310 are formed on the exposed portions of the insulator layer 138.

A deposition tool may be used to deposit the spacer layers 308 and/or 310 using a PVD technique, an ALD technique, a CVD technique, an oxidation technique, and/or another suitable deposition technique. The spacer layers 308 and/or 310 may be deposited in one or more deposition operations. In some implementations, a planarization tool may be used to perform a planarization operation (e.g., a CMP operation) to planarize the spacer layers 308 and/or 310 after the spacer layers 308 and/or 310 are deposited.

As shown in FIG. 3M, the spacer layers 308 and 310 are etched along with portions of the insulator layer 138, portions of the bottom electrode layer 136, portions of the adhesion layer 134, and portions of the metal-containing layer 152 to define the bottom electrode layer 136 of the MIM structure of the trench capacitor structure 126. The etch operation may be referred to as a CBM etch operation. In some implementations, the etch operation includes a dry etch operation (e.g., a plasma-based etch operation, a gas-based etch operation), a wet chemical etch operation, and/or another type of etch operation. Etching of the spacer layers 308 and 310 removes portions of the spacer layers 308 and 310 from the top of the nitride capping layer 146, resulting information of the sidewall spacers 148 and 150 on the ends of the oxide capping layer 142, the ends of oxynitride capping layer 144, the ends of the nitride capping layer 146, and the ends of the top electrode layer 140. Moreover, etching of the spacer layers 308 and 310 results in the sidewall spacers 150 having rounded outer surfaces.

An etchant (e.g., a gas-based etchant, a plasma-based etchant) may be used to achieve an anisotropic etch of the spacer layers 308 and 310. The spacer layers 308 and 310 may be etched along with portions of the insulator layer 138, portions of the bottom electrode layer 136, portions of the adhesion layer 134, and portions of the metal-containing layer 152. The anisotropic etch primarily etches in the z-direction in the semiconductor device 100, enabling minimal lateral etching of the bottom electrode layer 136 and of the insulator layer 138 to be achieved. The etchant that is used may have different etch rates for the metal-containing layer 152 and the bottom electrode layer 136. For example, a ratio of an etch rate of the bottom electrode layer 136 to an etch rate of the metal-containing layer 152 for the etchant may be included in a range of approximately 50:1 to approximately 150:1. If the ratio is too low (meaning that the etch rates for the metal-containing layer 152 and the bottom electrode layer 136 are too similar), the metal-containing layer 152 may be etched through too quickly, resulting in increased likelihood of etching into the underlying ILD layer 114d. If the ratio is too high (meaning that the etch rate for the bottom electrode layer 136 is much higher than the etch rate for the metal-containing layer 152), the likelihood of residual material of the metal-containing layer 152 remaining exposed is increased (which may increase the likelihood of the metal-containing layer 152 causing electrical shorting in the semiconductor device 100). If the ratio is included in the range of range of approximately 50:1 to approximately 150:1, the likelihood that the exposed portions of the metal-containing layer 152 are fully removed is increased with minimal etching into the ILD layer 114d. However, other values for the ratio, and ranges other than approximately 50:1 to approximately 150:1, are within the scope of the present disclosure.

As shown in FIG. 3N, additional material of the ILD layer 114d may be formed to encapsulate the trench capacitor structure 126. A deposition tool may be used to deposit the additional material of the ILD layer 114d using a PVD technique, an ALD technique, a CVD technique, an epitaxy technique, an oxidation technique, and/or another suitable deposition technique. The additional material of the ILD layer 114d may be deposited in one or more deposition operations. In some implementations, a planarization tool may be used to perform a planarization operation (e.g., a CMP operation) to planarize the ILD layer 114d after the additional material of the ILD layer 114d is deposited.

As shown in FIG. 30, a recess 312 may be formed in the ILD layer 114d, through the capping layers 142-146, and to the top electrode layer 140 of the trench capacitor structure 126. Thus, the top electrode layer 140 may be exposed through the recess 312.

In some implementations, a pattern in a photoresist layer is used to etch the ILD layer 114d, the oxide capping layer 142, the oxynitride capping layer 144, and/or the nitride capping layer 146 to form the recess 312. In these implementations, a deposition tool may be used to form the photoresist layer on the ILD layer 114d. An exposure tool may be used to expose the photoresist layer to a radiation source to pattern the photoresist layer. A developer tool may be used to develop and remove portions of the photoresist layer to expose the pattern. An etch tool may be used to etch the ILD layer 114d, the oxide capping layer 142, the oxynitride capping layer 144, and/or the nitride capping layer 146 based on the pattern to form the recess 312. In some implementations, one or more etch operations are performed to etch the ILD layer 114d, the oxide capping layer 142, the oxynitride capping layer 144, and/or the nitride capping layer 146. In some implementations, the one or more etch operations may include a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 312 based on a pattern.

As shown in FIG. 3P, the top contact 130 may be formed in the recess 312. A deposition tool may be used to deposit the material of the top contact 130 using a CVD technique, a PVD technique, an ALD technique, an electroplating technique, and/or another suitable deposition technique. The top contact 130 may be deposited in one or more deposition operations. In some implementations, a seed layer is first deposited, and the top contact 130 is deposited on the seed layer. In some implementations, a planarization tool is used to perform a planarization operation (e.g., a CMP operation) to planarize the top contact 130 after the top contact 130 is deposited.

As indicated above, FIGS. 3A-3P are provided as an example. Other examples may differ from what is described with regard to FIGS. 3A-3P.

FIG. 4 is a flowchart of an example process 400 associated with forming a semiconductor device described herein. In some implementations, one or more process blocks of FIG. 4 are performed using one or more semiconductor processing tools, such as a deposition tool, an exposure tool, a developer tool, an etch tool, a planarization tool, an annealing tool, a wafer/die transport tool, and/or another type of semiconductor processing tool.

As further shown in FIG. 4, process 400 may include forming a pattern in a metal-containing masking layer on a first dielectric layer of a semiconductor device (block 410). For example, one or more semiconductor processing tools may be used to form a pattern (e.g., a pattern 306) in a metal-containing masking layer (e.g., a metal-containing layer 152) on a first dielectric layer (e.g., an ILD layer 114d) of a semiconductor device (e.g., a semiconductor device 100), as described herein.

As further shown in FIG. 4, process 400 may include forming, based on the pattern, a trench (132) through the first dielectric layer and a plurality of second dielectric layers to a conductive structure (block 420). For example, one or more semiconductor processing tools may be used to form, based on the pattern, a trench (e.g., a trench 132) through the first dielectric layer and a plurality of second dielectric layers (e.g., an ESL 116a, an ILD layer 114b, an ESL 116b, an ILD layer 114c, an ESL 116c) to a conductive structure (e.g., a bottom contact 128), as described herein.

As further shown in FIG. 4, process 400 may include forming an MIM capacitor structure of the semiconductor device in the trench (block 430). For example, one or more semiconductor processing tools may be used to form an MIM capacitor structure (e.g., a trench capacitor structure 126) of the semiconductor device in the trench, as described herein.

Process 400 may include additional implementations, such as any single implementation or any combination of implementations described below and/or in connection with one or more other processes described elsewhere herein.

In a first implementation, forming the MIM capacitor structure includes forming a portion of the MIM capacitor structure (e.g., a portion of an adhesion layer 134 of the trench capacitor structure 126, a portion of a bottom electrode layer 136 of the trench capacitor structure 126, a portion of an insulator layer 138 of the trench capacitor structure 126, a portion of a top electrode layer 140 of the trench capacitor structure 126) on the metal-containing masking layer.

In a second implementation, alone or in combination with the first implementation, forming the pattern in the metal-containing masking layer includes etching the metal-containing masking layer using a chlorine-based etchant (e.g., a Clₓ-based etchant such as a Cl₂-based etchant) to transfer the pattern from a photoresist layer (e.g., a photoresist layer 304) to the metal-containing masking layer.

In a third implementation, alone or in combination with one or more of the first and second implementations, forming the pattern includes etching the first dielectric layer and the plurality of second dielectric layers using a carbon fluoride-based etchant (e.g., CFₓ-containing etchant, such as a CF₄-containing etchant).

In a fourth implementation, alone or in combination with one or more of the first through third implementations, the metal-containing masking layer includes at least one of a metal-nitride material (e.g., a titanium nitride (TiN) material), or a metal-carbide material (e.g., a tungsten carbide (WC) material).

In a fifth implementation, alone or in combination with one or more of the first through fourth implementations, forming the metal-containing masking layer includes forming the metal-containing masking layer to a thickness (e.g., dimension D2) that is included in a range of approximately 400 angstroms to approximately 600 angstroms.

In a sixth implementation, alone or in combination with one or more of the first through fifth implementations, the thickness (e.g., dimension D4) of the metal masking layer after forming the trench is included in a range of approximately 150 angstroms to approximately 350 angstroms.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

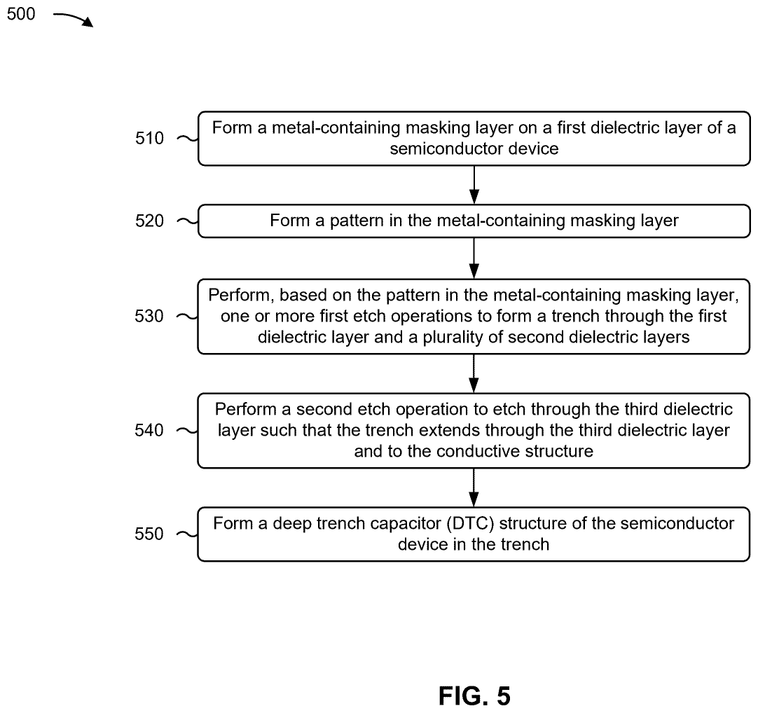

FIG. 5 is a flowchart of an example process 500 associated with forming a semiconductor device described herein. In some implementations, one or more process blocks of FIG. 5 are performed using one or more semiconductor processing tools, such as a deposition tool, an exposure tool, a developer tool, an etch tool, a planarization tool, an annealing tool, a wafer/die transport tool, and/or another type of semiconductor processing tool.

As shown in FIG. 5, process 500 may include forming a metal-containing masking layer on a first dielectric layer of a semiconductor device (block 510). For example, one or more semiconductor processing tools may be used to form a metal-containing masking layer (e.g., a metal-containing layer 152) on a first dielectric layer (e.g., an ILD layer 114d) of a semiconductor device (e.g., a semiconductor device 100), as described herein.

As further shown in FIG. 5, process 500 may include forming a pattern in the metal-containing masking layer (block 520). For example, one or more semiconductor processing tools may be used to form a pattern (e.g., a pattern 306) in the metal-containing masking layer, as described herein.

As further shown in FIG. 5, process 500 may include performing, based on the pattern in the metal-containing masking layer, one or more first etch operations to form a trench through the first dielectric layer and a plurality of second dielectric layers (block 530). For example, one or more semiconductor processing tools may be used to perform, based on the pattern in the metal-containing masking layer, one or more first etch operations to form a trench (e.g., a trench 132) through the first dielectric layer and a plurality of second dielectric layers (e.g., an ESL 116a, an ILD layer 114b, an ESL 116b, an ILD layer 114c, an ESL 116c), as described herein. In some implementations, the trench is formed above a conductive structure (e.g., a bottom contact 128) in the semiconductor device. In some implementations, a third dielectric layer (e.g., an ESL 116a) is between a bottom of the trench and the conductive structure after the one or more first etch operations.

As further shown in FIG. 5, process 500 may include performing a second etch operation to etch through the third dielectric layer such that the trench extends through the third dielectric layer and to the conductive structure (block 540). For example, one or more semiconductor processing tools may be used to perform a second etch operation to etch through the third dielectric layer such that the trench extends through the third dielectric layer and to the conductive structure, as described herein.

As further shown in FIG. 5, process 500 may include forming a DTC structure of the semiconductor device in the trench (block 550). For example, one or more semiconductor processing tools may be used to form a DTC structure (e.g., a trench capacitor structure 126) of the semiconductor device in the trench, as described herein.

Process 500 may include additional implementations, such as any single implementation or any combination of implementations described below and/or in connection with one or more other processes described elsewhere herein.

In a first implementation, forming the pattern in the metal-containing masking layer includes etching the metal-containing masking layer using a first etchant to form the pattern, and performing the one or more first etch operations includes performing the one or more first etch operations using a second etchant, where the first etchant and the second etchant are different etchants.

In a second implementation, alone or in combination with the first implementation, the first etchant includes a chlorine-based etchant (e.g., a Clₓ-based etchant such as a Cl₂-based etchant), and the second etchant comprises a fluorine-based etchant (e.g., CFₓ-containing etchant, such as a CF₄-containing etchant).

In a third implementation, alone or in combination with one or more of the first and second implementations, performing the second etch operation includes performing the second etch operation based on the pattern in the metal-containing masking layer, and without removing the metal-containing masking layer between the one or more first etch operations and the second etch operation.

In a fourth implementation, alone or in combination with one or more of the first through third implementations, forming the DTC structure includes forming the DTC structure such that layers of the DTC structure are formed on the metal-containing masking layer.

In a fifth implementation, alone or in combination with one or more of the first through fourth implementations, process 500 includes performing a third etch operation to define a top electrode layer (e.g., a top electrode layer 140) of the layers of the DTC structure, and performing a fourth etch operation to define a bottom electrode layer (e.g., a bottom electrode layer 136) of the layers of the DTC structure, where the metal-containing masking layer is etched in the fourth etch operation.

In a sixth implementation, alone or in combination with one or more of the first through fifth implementations, a ratio of an etch rate of the metal-containing masking layer to an etch rate of the bottom electrode layer in the fourth etch operation is included in a range of approximately 50:1 to approximately 150:1.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, a trench for a trench capacitor structure is formed using a metal-containing masking layer. The metal-containing masking layer enables the layers of a semiconductor device to be etched to form the trench in a manner that reduces and/or minimizes corner rounding at the top of the trench. In particular, the metal-containing masking layer suppresses etching in the corners at the top of the trench in that the metal masking-containing layer can be used for multiple etch operations and does not need to be removed between etch operations because of contamination concerns. This enables the metal-containing masking layer to be used to fully form the trench to a bottom contact, which enables the metal-containing masking layer to protect the top of the trench from corner rounding. In this way, enhanced critical dimension control at the top of the trench and higher aspect ratios may be achieved for the trench with minimal to no corner rounding using the metal-containing masking layer.

As described in greater detail above, some implementations described herein provide a method. The method includes forming a metal-containing masking layer on a first dielectric layer of a semiconductor device. The method includes forming a pattern in the metal-containing masking layer. The method includes forming, based on the pattern, a trench through the first dielectric layer and a plurality of second dielectric layers to a conductive structure. The method includes forming an MIM capacitor structure of the semiconductor device in the trench.

As described in greater detail above, some implementations described herein provide a method. The method includes forming a metal-containing masking layer on a first dielectric layer of a semiconductor device. The method includes forming a pattern in the metal-containing masking layer. The method includes performing, based on the pattern in the metal-containing masking layer, one or more first etch operations to form a trench through the first dielectric layer and a plurality of second dielectric layers, where the trench is formed above a conductive structure in the semiconductor device, and where a third dielectric layer is between a bottom of the trench and the conductive structure after the one or more first etch operations. The method includes performing a second etch operation to etch through the third dielectric layer such that the trench extends through the third dielectric layer and to the conductive structure. The method includes forming a DTC structure of the semiconductor device in the trench.

As described in greater detail above, some implementations described herein provide a semiconductor device. The semiconductor device includes a device layer. The semiconductor device includes one or more integrated circuit devices in the device layer. The semiconductor device includes an interconnect layer above the device layer. The semiconductor device includes a trench capacitor structure in the interconnect layer. The trench capacitor structure includes a bottom electrode layer along sidewalls and bottom surfaces of a plurality of trenches in the interconnect layer, an insulator layer on the bottom electrode layer, a top electrode layer on the insulator layer, and a metal-containing layer between the plurality of trenches.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a pattern in a metal-containing masking layer on a first dielectric layer of a semiconductor device;
forming, based on the pattern, a trench through the first dielectric layer and a plurality of second dielectric layers to a conductive structure; and
forming a metal-insulator-metal (MIM) capacitor structure of the semiconductor device in the trench.

2. The method of claim 1, wherein forming the MIM capacitor structure comprises:
forming a portion of the MIM capacitor structure on the metal-containing masking layer.

3. The method of claim 1, wherein forming the pattern in the metal-containing masking layer comprises:
etching the metal-containing masking layer using a chlorine-based etchant to transfer the pattern from a photoresist layer to the metal-containing masking layer.

4. The method of claim 3, wherein forming the pattern comprises:
etching the first dielectric layer and the plurality of second dielectric layers using a carbon fluoride-based (CFₓ) etchant.

5. The method of claim 1, wherein the metal-containing masking layer comprises at least one of:
a metal-nitride material, or
a metal-carbide material.

6. The method of claim 1, wherein forming the metal-containing masking layer comprises:
forming the metal-containing masking layer to a thickness that is included in a range of approximately 400 angstroms to approximately 600 angstroms.

7. The method of claim 6, wherein the thickness of the metal masking layer after forming the trench is included in a range of approximately 150 angstroms to approximately 350 angstroms.

8. A method, comprising:
forming a metal-containing masking layer on a first dielectric layer of a semiconductor device;
forming a pattern in the metal-containing masking layer;
performing, based on the pattern in the metal-containing masking layer, one or more first etch operations to form a trench through the first dielectric layer and a plurality of second dielectric layers,
wherein the trench is formed above a conductive structure in the semiconductor device, and
wherein a third dielectric layer is between a bottom of the trench and the conductive structure after the one or more first etch operations;
performing a second etch operation to etch through the third dielectric layer such that the trench extends through the third dielectric layer and to the conductive structure; and
forming a deep trench capacitor (DTC) structure of the semiconductor device in the trench.

9. The method of claim 8, wherein forming the pattern in the metal-containing masking layer comprises:
etching the metal-containing masking layer using a first etchant to form the pattern;
wherein performing the one or more first etch operations comprises:
performing the one or more first etch operations using a second etchant; and
wherein the first etchant and the second etchant are different etchants.

10. The method of claim 9, wherein the first etchant comprises a chlorine-based etchant; and
wherein the second etchant comprises a fluorine-based etchant.

11. The method of claim 8, wherein performing the second etch operation comprises:
performing the second etch operation based on the pattern in the metal-containing masking layer, and without removing the metal-containing masking layer between the one or more first etch operations and the second etch operation.

12. The method of claim 8, wherein forming the DTC structure comprises:
forming the DTC structure such that layers of the DTC structure are formed on the metal-containing masking layer.

13. The method of claim 12, further comprising:
performing a third etch operation to define a top electrode layer of the layers of the DTC structure; and
performing a fourth etch operation to define a bottom electrode layer of the layers of the DTC structure,
wherein the metal-containing masking layer is etched in the fourth etch operation.

14. The method of claim 13, wherein a ratio of an etch rate of the bottom electrode layer to an etch rate of the metal-containing masking layer in the fourth etch operation is included in a range of approximately 50:1 to approximately 150:1.

15. A semiconductor device, comprising:
a device layer;
one or more integrated circuit devices in the device layer;
an interconnect layer above the device layer; and
a trench capacitor structure in the interconnect layer,
wherein the trench capacitor structure comprises:
a bottom electrode layer along sidewalls and bottom surfaces of a plurality of trenches in the interconnect layer;
an insulator layer on the bottom electrode layer;
a top electrode layer on the insulator layer; and
a metal-containing layer between the plurality of trenches.

16. The semiconductor device of claim 15, wherein the metal-containing layer comprises at least one of:
titanium nitride (TiN), or
tungsten carbide (WC).

17. The semiconductor device of claim 15, wherein the metal-containing layer has a rounded edge between a sidewall of the metal-containing layer and a top of the metal-containing layer; and
wherein an angle of the rounded edge, relative to the sidewall, is included in a range of approximately 100 degrees to approximately 110 degrees.

18. The semiconductor device of claim 15, wherein the bottom electrode layer, the insulator layer, and the top electrode layer continuously extend over the metal-containing layer between the plurality of trenches.

19. The semiconductor device of claim 15, wherein the trench capacitor structure further comprises:
an adhesion layer between the metal-containing layer and the bottom electrode layer.

20. The semiconductor device of claim 19, wherein the adhesion layer is in physical contact with a top surface of the metal-containing layer and sidewalls of the metal-containing layer.
